(19) United States
(12) Patent Application Publication
(10) Pub. No.: US 2026/0198028 A1
(43) Pub. Date: Jul. 9, 2026

(54) REMOVAL OF INTERPOSER LAYER

(71) Applicant: Taiwan Semiconductor Manufacturing Company, Ltd., Hsinchu (TW)

(72) Inventors: Shu-Uei Jang, Hsinchu City (TW); Chih Li Chang, Hsinchu (TW); Wen-Shuo Hsieh, Taipei City (TW); Shih-Yao Lin, New Taipei City (TW)

(73) Assignee: Taiwan Semiconductor Manufacturing Company, Ltd., Hsinchu (TW)

(21) Appl. No.: 19/012,154

(22) Filed: Jan. 7, 2025

(51) Int. Cl. H10D 30/01; H10D 62/00

(52) U.S. Cl. CPC H10D 30/0195; H10D 30/014; H10D 62/021

(57) ABSTRACT

Provided are semiconductor structures and methods for fabricating semiconductor structures. A method includes in a first device region and in a second device region: forming a stack of first epitaxial layers and second epitaxial layers; forming a sacrificial gate over the stack; etching the stack to form a cavity having a bottom surface; removing the first epitaxial layers to form gaps; and depositing an interposer material over the bottom surface and in the gaps; in the first device region: performing an anisotropic etch of the interposer material located over the bottom surface; and in the first device region and in the second device region: performing an isotropic etch of the interposer material to remove the interposer material located over the bottom surface and to laterally recess the interposer material in the gaps.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating a method, in accordance with some embodiments.

FIGS. 2-6 are perspective views of a structure of the semiconductor device during successive stages of fabrication, in accordance with some embodiments.

FIG. 7 is a cross-sectional view of the structure of the semiconductor device in FIG. 6, in accordance with some embodiments.

FIG. 8 is a cross-sectional view of the structure of the semiconductor device in a successive fabrication stage, in accordance with some embodiments.

FIGS. 9-11 are perspective views of the structure of the semiconductor device in successive fabrication stages, in accordance with some embodiments.

FIG. 12-17 are cross-sectional views of the structure of the semiconductor device in successive fabrication stages, in accordance with some embodiments.

FIGS. 18-19 are perspective views of the structure of the semiconductor device at selected fabrication stages, in accordance with some embodiments.

FIG. 20 is a cross-sectional view of the structure of the semiconductor device at a selected fabrication stage, in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. As used herein, “directly over” refers to a vertical alignment of features such that, when an overlying feature that is directly over an underlying feature, a vertical axis passes through both features. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “directly over”, “over”, “overlying”, “above”, “upper”, “top”, “under”, “underlying”, “beneath”, “below”, “lower”, “bottom”, “side”, “positive slope” and “negative slope” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

All numbers in this description indicating amounts, ratios of materials, physical properties of materials, and/or use are to be understood as modified by the word “about,” except as otherwise explicitly indicated. When modifying a numerical value in the specification or claims, “about” denotes an interval of accuracy, familiar and acceptable to a person skilled in the art. In general, such interval of accuracy is ±ten percent. Thus, “about ten” means nine to eleven.

In certain embodiments herein, a “material layer” is a layer that includes at least 50 wt. % of the identified material, for example at least 60 wt. % of the identified material, at least 75 wt. % of the identified material, at least 90 wt. % of the identified material, or at least 99 wt. % of the identified material; and a layer that is a “material” includes at least 50 wt. % of the identified material, for example at least 60 wt. % of the identified material, at least 75 wt. % of the identified material, at least 90 wt. % of the identified material, or at least 99 wt. % of the identified material. For example, certain embodiments, each of a titanium nitride layer and a layer that is titanium nitride is a layer that is at least 50 wt. %, at least 60 wt. %, at least 75 wt. %, titanium nitride, at least 90 wt. % titanium nitride, or at least 99 wt. % titanium nitride.

For the sake of brevity, well-known techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Certain embodiments herein are generally related to multi-gate transistors. Multi-gate transistors include those transistors whose gate structures are formed on at least two-sides of a channel region. These multi-gate devices may include a p-type metal-oxide-semiconductor device or an n-type metal-oxide-semiconductor multi-gate device. Specific examples may be presented and referred to herein as gate-all-around (GAA) devices. A GAA device includes any device that has its gate structure, or portion thereof, formed on four sides of a channel region (e.g., surrounding a portion of a channel region).

It is noted that while the Figures and description recite the structure of a gate-all-around (GAA) device, it is contemplated that the methods described herein may be used to fabricate other types of devices, and that the devices described herein may be other types of devices.

Structures presented herein also include embodiments that have channel regions in the form of nanosheets. The term “nanosheet” designates any material portion with nanoscale, or even microscale dimensions, and having an elongated shape, regardless of the cross-sectional shape of this portion. Thus, this term designates both circular and substantially circular cross-section elongated material portions, e.g., nanowires, and beam or bar-shaped material portions including for example a cylindrical or substantially rectangular cross-section.

In devices such as NSFET/GAAFET, achieving good top-to-bottom loading in gate-all-around (dummy gate replacement) is crucial for device performance and yield. With numerous devices on the SoC (system-on-chip), it is also important to control pattern loading in the gate-all-around process. However, ODW (OD width) loading issues may result in residual disposable oxide in the gate-all-around process. The oxide diffusion area, or OD area or active area, in a semiconductor device is the active area for each transistor. This is where the source, drain, and channel under the transistor gate are formed. The OD is between inactive areas, such as shallow trench isolation (STI) or field oxide (FOX) areas.

In embodiments, methods are provided to remove the residual disposable oxide, such as in source/drain regions where source/drain features are formed.

Certain embodiments provide for removing more disposable oxide in a vertical direction than in a lateral direction. For example, a direction etch may be used to remove or recess a trench bottom portion of disposable oxide while lateral surfaces of inter-nanosheet portions of the disposable oxide are not etched, or are only etched by a negligible amount, in the lateral direction.

Certain embodiments provide for masking semiconductor device regions where devices have a large OD width, i.e., from 5 nm to 100 nm, while semiconductor device regions where devices have a small OD width, i.e., from 2 nm to 30 nm, are directionally etched to remove or recess disposable oxide layers. In certain embodiments, the large OD width is at least 2 nm greater than the small OD width.

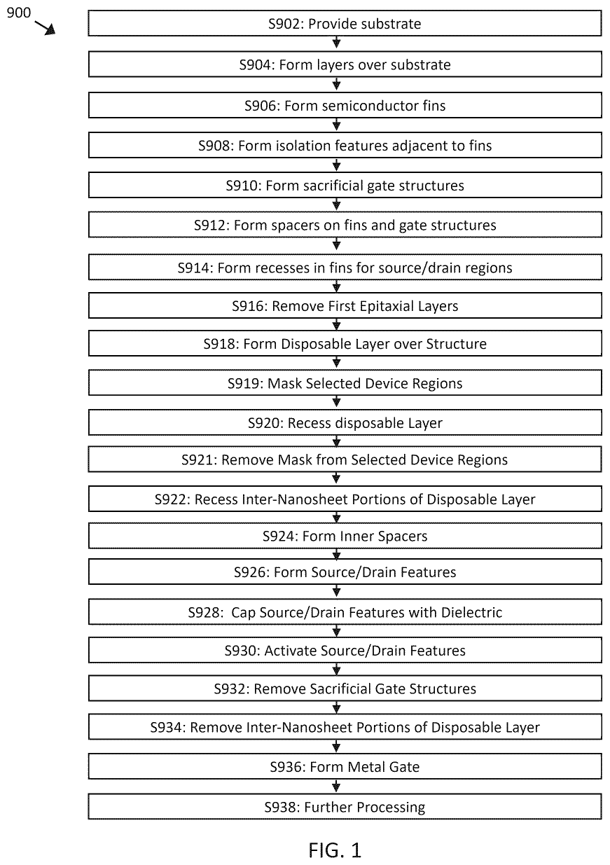

Referring now to FIG. 1, a method 900 for forming a structure, such as a multi-gate device, is illustrated in a flow chart, according to various aspects of the present disclosure. As used herein, the term “multi-gate device” is used to describe a device (e.g., a semiconductor transistor) that has at least some gate material disposed on multiple sides of at least one channel of the device. In some examples, the multi-gate device may be referred to as a GAA device having gate material disposed on four sides of at least one channel member of the device. The channel member may be referred to as a “nanosheet”.

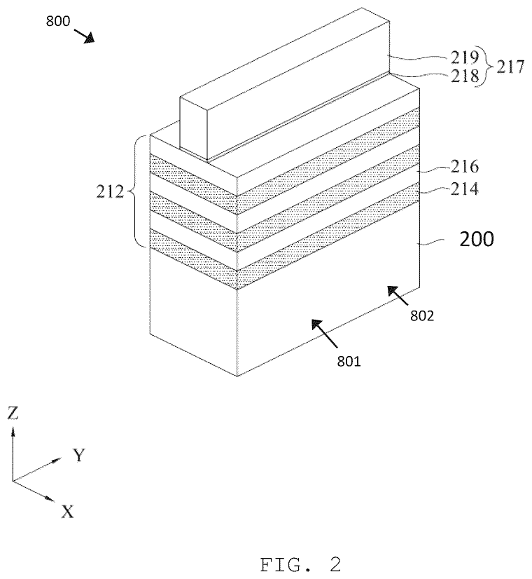

FIG. 1 is described in conjunction with FIGS. 2-17, which illustrate a semiconductor device 800 at various stages of fabrication in accordance with some embodiments of the present disclosure of the method 900. The method 900 is merely an example, and is not intended to limit the present disclosure beyond what is explicitly recited in the claims. Additional steps may be provided before, during, and after method 900, and some of the steps described can be moved, replaced, or eliminated for additional embodiments of method 900. Additional features may be added in the semiconductor device depicted in the Figures and some of the features described below can be replaced, modified, or eliminated in other embodiments of the semiconductor device.

As with other method embodiments and exemplary devices discussed herein, it is understood that parts of the semiconductor device 800 may be fabricated by typical semiconductor technology process flow, and thus some processes are only briefly described herein. Further, the exemplary semiconductor devices may include various other devices and features, such as other types of devices such as additional transistors, bipolar junction transistors, resistors, capacitors, inductors, diodes, fuses, and/or other logic devices, etc., but is simplified for a better understanding of concepts of the present disclosure. In some embodiments, the exemplary devices include a plurality of semiconductor devices (e.g., transistors), including PFETs, NFETs, etc., which may be interconnected. Moreover, it is noted that the process steps of method 900, including any descriptions given with reference to the Figures, as with the remainder of the method and exemplary figures provided in this disclosure, are merely exemplary and are not intended to be limiting beyond what is specifically recited in the claims that follow.

At operation S902, the method 900 (FIG. 1) provides a substrate 200, as shown in FIG. 2. In some embodiments, the substrate 200 may be a semiconductor substrate such as a silicon (Si) substrate. The substrate 200 may include various layers, including conductive or insulating layers formed on a semiconductor substrate. The substrate 200 may include various doping configurations depending on design requirements as is known in the art. For example, different doping profiles (e.g., p-well, n-well) may be formed on the substrate 200 in regions designed for different device types (e.g., n-type field effect transistors (NFET), p-type field effect transistors (PFET)). The suitable doping may include ion implantation of dopants and/or diffusion processes, such as boron (B) for the p-well and phosphorous (P) for the n-well. In some embodiments, the substrate 200 includes a single crystalline semiconductor layer on at least its surface portion. The substrate 200 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 200 may include a compound semiconductor and/or an alloy semiconductor. In the illustrated embodiment, the substrate 200 is made of crystalline Si.

As shown in FIG. 2, at operation S904, the method 900 (FIG. 1) forms one or more epitaxial layers over the substrate 200. In some embodiments, an epitaxial stack 212 is formed over the substrate 200. The epitaxial stack 212 includes epitaxial layers 214 of a first composition interposed by epitaxial layers 216 of a second composition. The first and second composition may be different. Embodiments are possible including those that provide for a first composition and a second composition having different oxidation rates and/or etch selectivity. As a result, the epitaxial layers 214 may be selectively removed to define the semiconductor layers 216 as nanosheet channel layers. In an embodiment, the epitaxial layers 214 are SiGe and the epitaxial layers 216 are silicon. In embodiments wherein the epitaxial layer 214 includes SiGe and the epitaxial layer 216 includes silicon, the silicon oxidation rate is less than the SiGe oxidation rate. It is noted that three layers of epitaxial layers 214 and three layers of epitaxial layers 216 are illustrated in FIG. 2, which is for illustrative purposes only and not intended to be limiting beyond what is specifically recited in the claims. It can be appreciated that any number of epitaxial layers may be formed in the epitaxial stack 212; the number of layers depending on the desired number of channels regions for the GAA device 800. In some embodiments, the number of epitaxial layers 216 is between two and ten, such as six or seven.

In some embodiments, the epitaxial layer 214 has a thickness ranging from 5 to 15 nm. The epitaxial layers 214 may be substantially uniform in thickness. In some embodiments, the epitaxial layer 216 has a thickness ranging from 5 to 15 nm. In some embodiments, the epitaxial layers 216 of the stack are substantially uniform in thickness. As described in more detail below, the epitaxial layer 216 may serve as channel region(s) for a subsequently formed multi-gate device and has a thickness chosen based on device performance considerations. The epitaxial layer 214 may serve to define a gap between adjacent channel region(s) for a subsequently formed multi-gate device and has a thickness chosen based on device performance considerations.

By way of example, epitaxial growth of the epitaxial stack 212 may be performed by a molecular beam epitaxy (MBE) process, a metalorganic chemical vapor deposition (MOCVD) process, and/or other suitable epitaxial growth processes. In some embodiments, the epitaxial layers 216 include the same material as the substrate 200. In some embodiments, the epitaxially grown layers 214 and 216 include a different material than the substrate 200. As stated above, in at least some examples, the epitaxial layer 214 includes an epitaxially grown Si₁₋ₓGeₓ layer (wherein x is from 0.10 to 0.55 and the epitaxial layer 216 includes an epitaxially grown silicon (Si) layer. Alternatively, in some embodiments, either of the epitaxial layers 214 and 216 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 214 and 216 may be chosen based on providing differing oxidation, etch selectivity properties. In various embodiments, the epitaxial layers 214 and 216 are substantially dopant-free (i.e., having an extrinsic dopant concentration from 0 cm⁻³ to 1×10¹⁷ cm⁻³), where for example, no intentional doping is performed during the epitaxial growth process. In some embodiments, the bottom layer and the top layer of the epitaxial stack 212 are SiGe layers (not shown). In alternative embodiments, the bottom layer of the epitaxial stack 212 is a Si layer and the top layer of the epitaxial stack 212 is a SiGe layer.

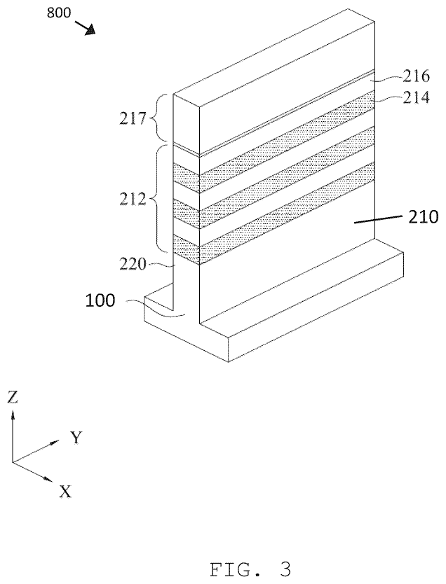

As shown in FIG. 3, at operation S906, the method 900 (FIG. 1) patterns the epitaxial stack 212 to form semiconductor fins 220. In some embodiments, the operation S906 includes forming a mask 217 over the epitaxial stack 212, as shown in FIG. 2. The mask 217 includes a first mask layer 218 and a second mask layer 219. An exemplary first mask layer 218 is a pad oxide layer made of a silicon oxide, which may be formed by a thermal oxidation. An exemplary second mask layer 219 is made of a silicon nitride (SiN), which may be formed by chemical vapor deposition (CVD), including low pressure CVD (LPCVD) and plasma enhanced CVD (PECVD), physical vapor deposition (PVD), atomic layer deposition (ALD), or other suitable process. The mask 217 is patterned into a mask pattern by using patterning operations including photolithography and etching.

As shown in FIG. 3, operation S906 subsequently patterns the epitaxial stack 212 in an etching process, such as a dry etch (e.g., reactive ion etching), a wet etch, and/or other suitable process, through openings defined in the patterned mask 217. The stacked epitaxial layers 214 and 216 are thereby patterned into the fin 220. While FIG. 3 illustrates the formation of one fin 220, any suitable number of fins may be formed. Trenches are etched between adjacent fins 220.

In various embodiments, each fin 220 includes an upper portion of the interleaved epitaxial layers 214 and 216, and a bottom portion, or mesa portion 210, that is formed from the etched substrate 200. Each fin 220 protrudes upwardly in the Z-direction from the substrate 200 and extends lengthwise in the Y-direction. Sidewalls of each fin 220 may be vertical or inclined (not shown). In FIG. 3, additional fins would be spaced apart along the X-direction. The fins 220 may have a same width or different widths.

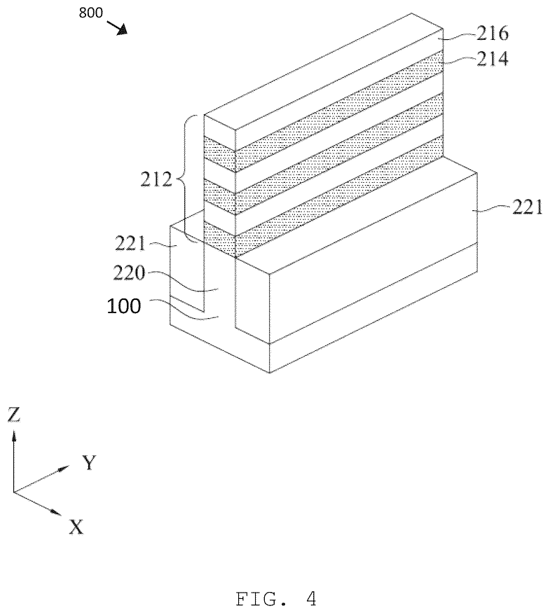

As shown in FIG. 4, at operation S908, the method 900 (FIG. 1) forms isolation features (also denoted as shallow trench isolation or STI features) 221 with a dielectric layer in trenches adjacent to each fin 220. The STI features 221 may be formed by first filling the trenches around each fin 220 with a dielectric material layer to cover top surfaces and sidewalls of the fin 220 (not shown). The dielectric material layer may include one or more dielectric materials. Suitable dielectric materials for the dielectric layer may include silicon oxides, silicon nitrides, silicon carbides, fluorosilicate glass (FSG), low-K dielectric materials, and/or other suitable dielectric materials. The dielectric material may be deposited by any suitable technique including thermal growth, flowable CVD (FCVD), HDP-CVD, PVD, ALD, and/or spin-on techniques. The dielectric material layer is then planarized by using, for example, chemical mechanical planarization (CMP), until top surfaces of the mask 217 are revealed, and the dielectric material layer is recessed to form the shallow trench isolation (STI) features (also denoted as STI features) 221, as shown in FIG. 4. In the illustrated embodiment, the STI features 221 are formed on the substrate 200. Any suitable etching technique may be used to recess the isolation features 221 including dry etching, wet etching, RIE, and/or other etching methods, and in an exemplary embodiment, an anisotropic dry etching is used to selectively remove the dielectric material of the isolation features 221 without etching the fin 220. The mask 217 (shown in FIG. 3) may also be removed before, during, and/or after the recessing of the isolation features 221. In some embodiments, the mask 217 is removed by the CMP process performed prior to the recessing of the isolation features 221. In some embodiments, the mask 217 is removed by an etchant used to recess the isolation features 221.

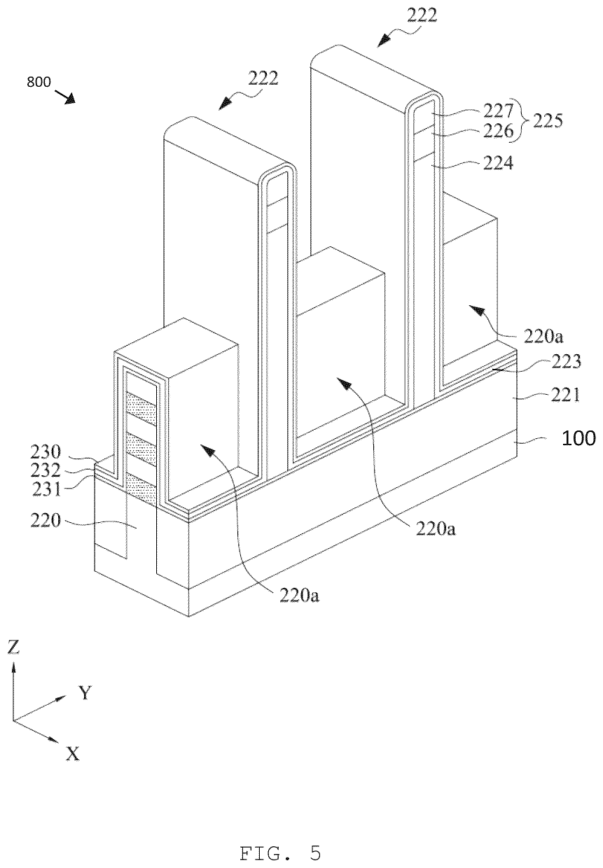

As shown in FIG. 5, at operation S910, the method 900 (FIG. 1) forms sacrificial (dummy) gate structures 222. The sacrificial gate structures 222 are formed over portions of the fin 220 which are to be channel regions. Specifically, the sacrificial gate structures 222 lie directly over and define the channel regions of the GAA devices to be formed. The sacrificial gate structures 222 may extend over a number of adjacent fins (not shown). Each of the sacrificial gate structures 222 includes a sacrificial gate dielectric 223 and a sacrificial gate electrode 224 over the sacrificial gate dielectric 223. As shown, the gate structures 222 extend lengthwise in the X-direction and are spaced apart in the Y-direction.

The sacrificial gate structures 222 are formed by first blanket depositing a sacrificial gate dielectric layer over the fin(s) 220. A sacrificial gate electrode layer is then blanket deposited on the sacrificial gate dielectric layer and over the fin(s) 220. The sacrificial gate dielectric layer includes silicon oxide, silicon nitride, or a combination thereof. The thickness of the sacrificial gate electrode layer is in a range from 100 to 200 nm in some embodiments. The sacrificial gate electrode layer 224 includes silicon such as polycrystalline silicon or amorphous silicon. The thickness of the sacrificial gate dielectric layer is in a range from 1 to 5 nm in some embodiments. In some embodiments, the sacrificial gate electrode layer is subjected to a planarization operation. The sacrificial gate dielectric layer and the sacrificial gate electrode layer are deposited using CVD, including LPCVD and PECVD, PVD, ALD, or other suitable process. A mask 225 is formed over the sacrificial gate electrode layer. The mask 225 may include a mask layer 226 such as silicon oxide and a mask layer 227 such as silicon nitride. Subsequently, a patterning operation is performed on the mask 225, the sacrificial gate electrode layers and the sacrificial gate dielectric layer are patterned into the sacrificial gate structures 222, including sacrificial gate dielectric layer 223 and sacrificial gate electrode 224.

As shown, the fin 220 is partially exposed, i.e., not covered by an overlying structure, between and on opposite sides of the sacrificial gate structures 222, thereby defining source/drain (S/D) regions. As used herein, “source/drain region(s)” or “source/drain feature(s)” may refer to a source or a drain, individually or collectively dependent upon the context.

Still referring to FIG. 5, at operation S912, the method 900 (FIG. 1) forms spacers 230 on sidewalls of the sacrificial gate structures 222 and sidewalls of the fins 220 by depositing spacer materials and then etching. The spacers 230 may include spacer material such as silicon oxide, silicon nitride, silicon carbide, silicon oxynitride, SiCN films, silicon oxycarbide, SiOCN films, and/or combinations thereof. In some embodiments, each of the spacers 230 include multiple layers, such as a liner layer 231 and a main spacer layer 232 over the liner layer 231.

By way of example, the spacers 230 may be formed by depositing spacer material including a liner material layer and a dielectric material layer over the sacrificial gate structures 222 using processes such as a subatmospheric CVD (SACVD) process, a flowable CVD process, an ALD process, a PVD process, or other suitable process respectively.

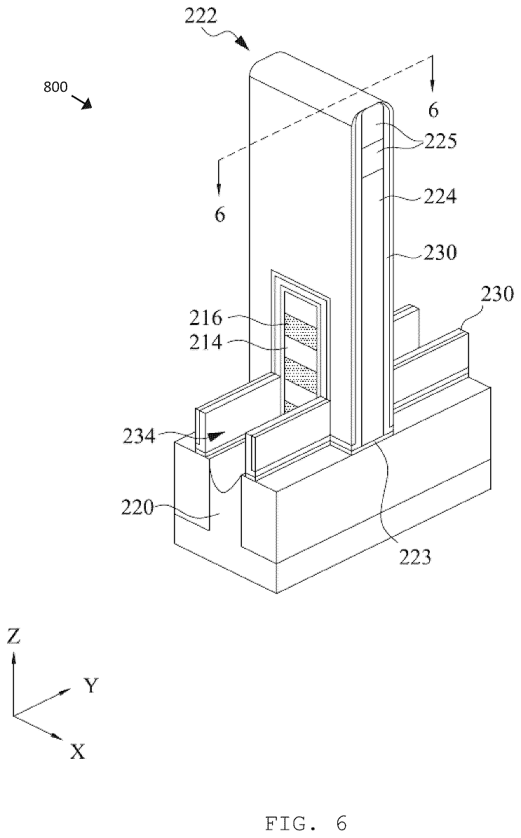

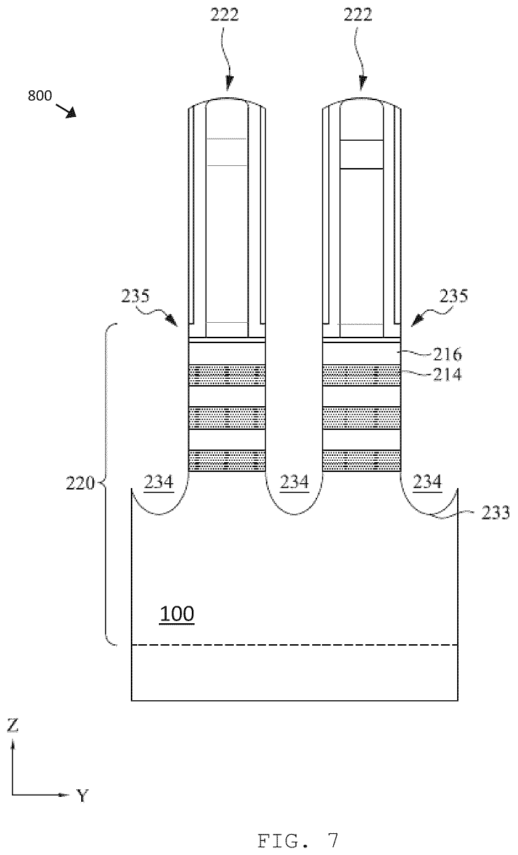

As shown in FIGS. 6 and 7, the deposition of the liner material layer and the dielectric material layer are followed by, at operation S914, an etching-back (e.g., anisotropic) process to expose, and remove, portions 220a of the fins 220 adjacent to and not covered by the sacrificial gate structure 222 (e.g., source/drain regions). Specifically, the method 900 (FIG. 1) recesses the portions of the fin 220 not covered by the sacrificial gate structures 222 to form gaps, recesses, or cavities 234 in the source/drain regions. It is noted that FIG. 6 shows only one sacrificial gate structure 222 and the adjacent portion of fin 220 so that etching of the S/D region between the sacrificial gate structures 222 of FIG. 5 may be more clearly viewed. FIG. 7 is a cross sectional-view along line 6-6 in FIG. 6 but, like FIG. 5, FIG. 7 illustrates both sacrificial gate structures 222 and the fin 220 adjacent to both sacrificial gate structures 222.

The liner material layer and the dielectric material layer may remain on the sidewalls of the sacrificial gate structure 222 as the gate sidewall spacers 230, and on the sidewalls of the fins as the fin sidewall spacers 230. In some embodiments, the etching-back process may include a wet etch process, a dry etch process, a multiple-step etch process, and/or a combination thereof. The spacers 230 may have a thickness ranging from 5 to 20 nm.

As shown most clearly in FIG. 7, the stacked epitaxial layers 214 and 216 and an upper portion of substrate 200 forming fin 220 are etched down at the S/D regions. As a result, bottom cavity surfaces 233 are formed in the fin 220. In some embodiments, the operation S914 forms the cavities 234 by a suitable etching process, such as a dry etching process, a wet etching process, or a combination thereof. As a result of the etching process, fin segments 235 of the upper portion of the fin 220 are defined and separated from one another by the cavities 234.

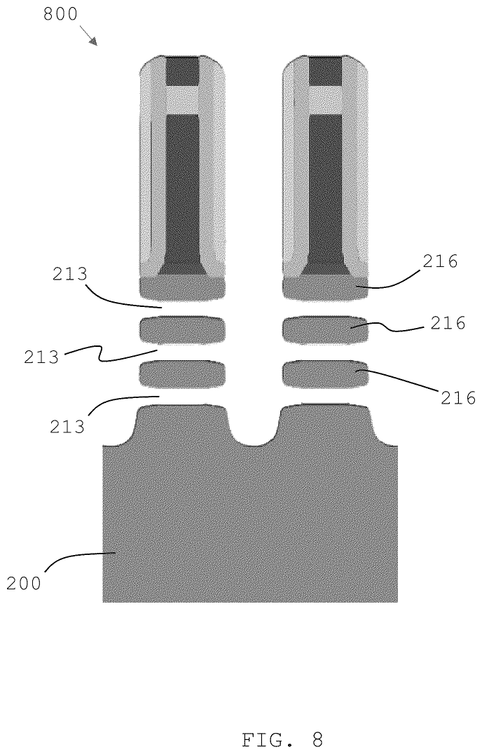

FIG. 8 provides the same cross-sectional view as FIG. 7, at a successive stage of fabrication. As shown in FIG. 8, at operation S916, the method 900 (FIG. 1) removes the first epitaxial layers 214, e.g., the SiGe layers 214. As a result, temporary gaps 213 are formed between the remaining second epitaxial layers 216. In an embodiment the layers 214 may be removed using a wet etching process that selectively removes the material of the first layers (e.g., silicon germanium (SiGe)) without significantly removing the material of the second layers 216 (e.g., silicon (Si)). However, any suitable removal process may be utilized.

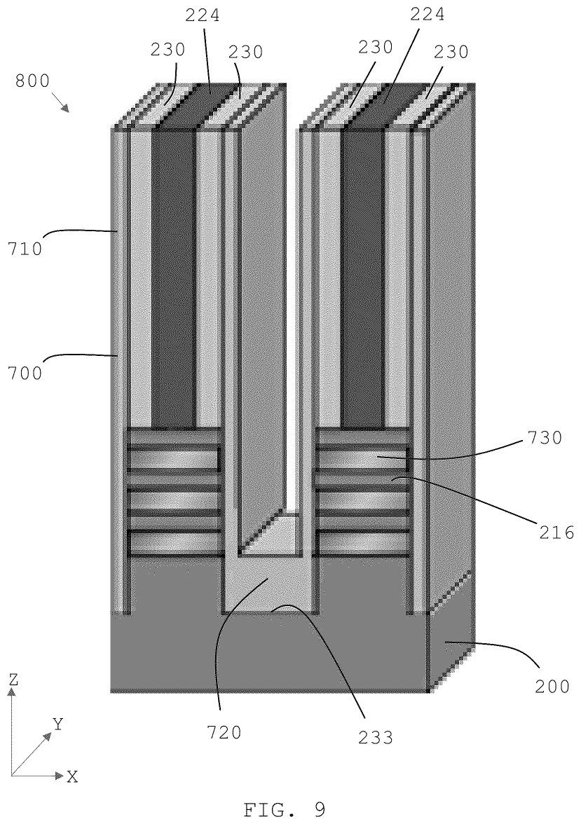

FIG. 9 provides a perspective view of a lower portion of the device 800 at a successive stage of fabrication. The mask 225 overlying the sacrificial gate electrode 224 is not illustrated. As shown in FIG. 9, at operation S918, the method 900 (FIG. 1) forms a disposable or sacrificial interposer material or layer 700 over the structure of the device 800. As shown, the interposer layer 700 is conformally deposited on the surfaces of sidewall spacers 230, over the bottom cavity surfaces 233, and in the temporary gaps 213. The interposer layer 700 may fill gaps 213. The interposer layer 700 includes sidewall portions 710, bottom portions 720, and inter-nanosheet portions 730. Further, the interposer layer 700 may be formed over the mask (not shown) overlying the sacrificial gate electrode 224.

In certain embodiments, the interposer layer 700 is an oxide material. For example, the interposer layer 700 may be silicon oxide. In certain embodiments, the interposer layer 700 is formed by a refill process. In certain embodiments the interposer layer 700 is formed by a flowable chemical vapor deposition (FCVD). In certain embodiments, the interposer layer 700 comprises multiple layers formed to control loading and/or shape of the layer 700. Further, in certain embodiments, the interposer layer 700 is formed by an initial deposition process followed by a refill process, such as an atomic layer deposition (ALD) process.

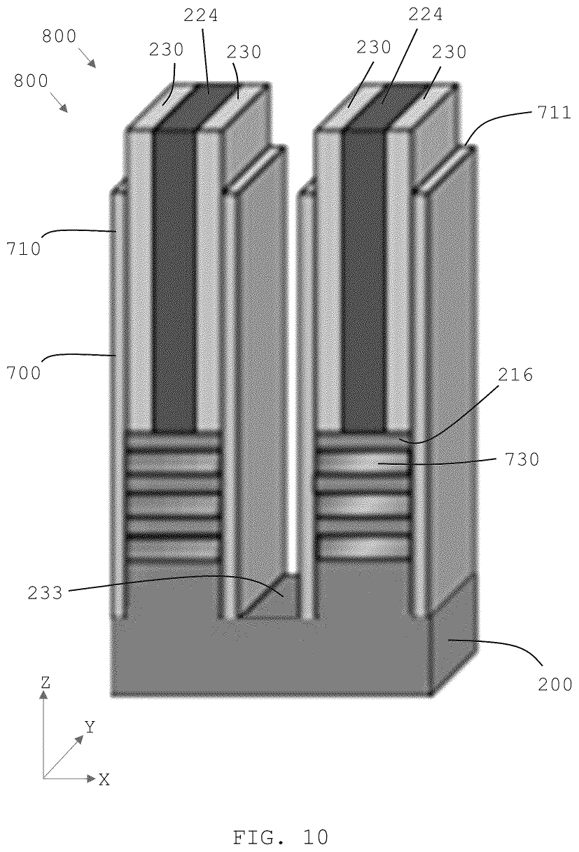

FIG. 10 provides the same perspective view as FIG. 9, at a successive stage of fabrication. As shown in FIG. 10, at operation S920, the method 900 (FIG. 1) includes performing an etch process to recess the interposer layer 700.

In certain embodiments, operation S920 includes performing an anisotropic etch or directional etch process, such as in a vertical direction, i.e., the Z-direction. For example, operation S920 may include performing a plasma etch process using bias power for directional control. The anisotropic etch process may use gaseous plasma of gases like CF₄+CHF₃, C₅F₈, and/or C₄F₈ with additive gases like N₂, Ar, and/or O₂. The etching reactors used may be parallel plate type with or without enhancement by magnetic fields or electron cyclotron resonance (ECR) type available commercially. A process recipe may include 400 watts RF power, 80 mtorr pressure, and a gas mixture of 10 sccm CF₄+90 sccm CHF₃+80 sccm Ar, with an etch time of approximately 15 seconds.

As shown in FIG. 10, the directional etch process may recess the sidewall portions 710 to a recessed upper surface 711. As shown, the recessed upper surface 711 of the sidewall portions 710 may be located at a height above, i.e., farther from substrate 200, than the uppermost inter-nanosheet portions 730, such as at a height above, i.e., farther from substrate 200, than the uppermost nanosheet 216.

As further shown in FIG. 10, the directional etch process may completely remove the bottom portions 720 such that no interposer layer 700 remains on the bottom cavity surfaces 233. In other embodiments, remnants of the bottom portions 720 may remain on the bottom cavity surfaces 233 after the directional etch process is performed.

As seen in the embodiment of FIG. 10, the inter-nanosheet portions 730 are not etched by the directional etch process.

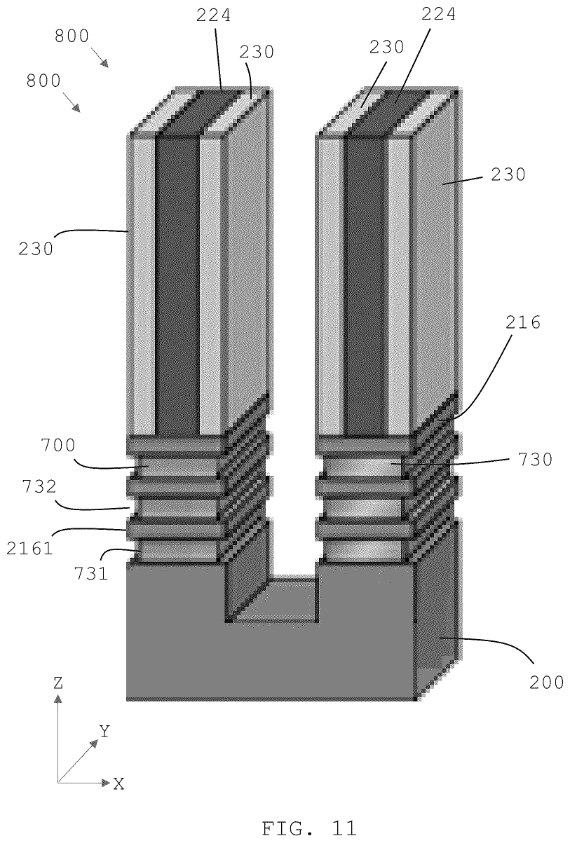

FIG. 11 provides the same perspective view as FIG. 10, at a successive stage of fabrication. As shown in FIG. 11, at operation S922, the method 900 (FIG. 1) includes performing an etch process to laterally recess the inter-nanosheet portions 730 of the interposer layer 700.

In certain embodiments, operation S922 includes performing an isotropic etch or non-directional etch process. For example, operation S922 may include performing a wet etch. In certain embodiments, operation S922 includes performing a wet etch process using dilute HF solution and/or an aqueous buffered HF solution. In certain embodiments, the etchant is selected to exhibit high selectivity to remove the interposer layer 700 as compared to removal of the substrate 200, nanosheet layers 216, or sidewall spacers 230.

As shown in FIG. 11, operation S922 may remove all of the sidewall portions 710. Further, if remnants of the bottom portions 720 remain after operation S920, then operation S922 may remove all remnants of the bottom portions 720.

In certain embodiments, a vertical thickness of any remnant of the bottom portions 720 remaining on the bottom cavity surface 233 after operation S922 is less than 0.4 nm, such as less than 0.3 nm, less than 0.25 nm, less than 0.2 nm, less than 0.15 nm, less than 0.1 nm, or less than 0.5 nm.

As shown, operation S922 laterally recesses the inter-nanosheet portions 730 to recessed surfaces 731. As shown, recessed surfaces 731 are distanced in the X-direction from the outer surfaces 2161 of the nanosheet layers 216. Thus, lateral recesses 732 are formed below and/or above nanosheets 216 and laterally adjacent to the recessed surfaces 731 of inter-nanosheet portions 730.

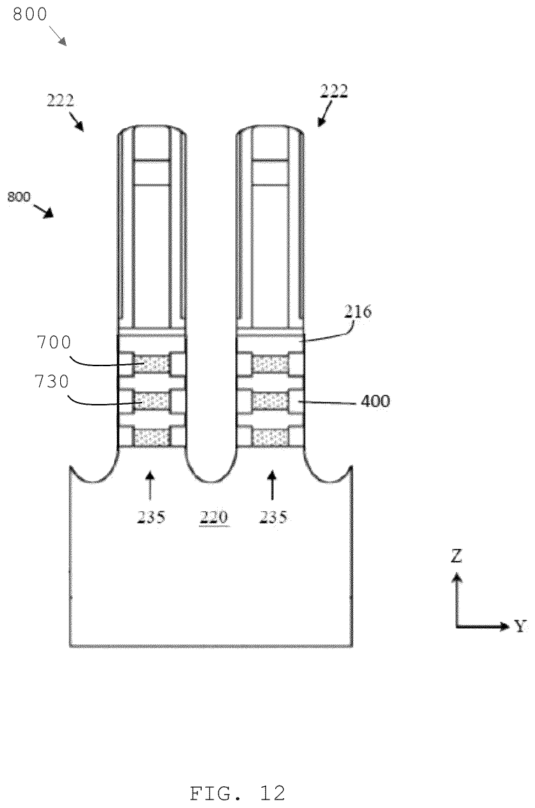

FIG. 12 provides a cross-sectional view of the device 800 at a successive stage of fabrication, such as along the same cross-section as FIG. 8. As shown in FIG. 12, at operation S924, the method 900 (FIG. 1) includes forming inner spacers 400 in the lateral recesses 732 adjacent to the laterally recessed inter-nanosheet portions 730 of interposer layer 700.

For example, operation S924 may include depositing an inner spacer material layer in the cavities 234 on the gap sidewalls, including on the recessed surfaces 731 of inter-nanosheet portions 730, and on the ends and top and bottom surfaces of the epitaxial layers 216, and on the bottom cavity surface 233. The inner spacer material layer may include silicon oxides, silicon nitrides, silicon carbides, silicon carbide nitride, silicon oxide carbide, silicon carbide oxynitride, and/or other suitable dielectric materials. In some embodiments, the inner spacer material layer is deposited as a conformal layer. The inner spacer material layer may be formed by ALD or any other suitable method. The inner spacer material layer may have a thickness ranging from 1 to 5 nm, for example from 1 to 4 nm, from 1 to 3 nm, or from 1 to 2 nm.

Operation S924 may further include trimming the inner spacer material layer. Removal of portions of the inner spacer material layer may be performed by an etching process, such as an anisotropic etching process, for example a dry etching process. In some embodiments, the dry etching process using an etchant including a fluorine-containing gas (e.g., SF₆, CF₄, CHF₃, CH₂F₂, and/or C₂F₆), a chlorine-containing gas (e.g., Cl₂), a bromine-containing gas (e.g., HBr and/or CHBR₃), oxygen-containing gas (e.g., O₂), a helium-containing gas (e.g., He), an argon-containing gas (e.g., Ar), other suitable gases, or combinations thereof. After this etching, the inner spacer material layer remains substantially within the lateral recesses 732.

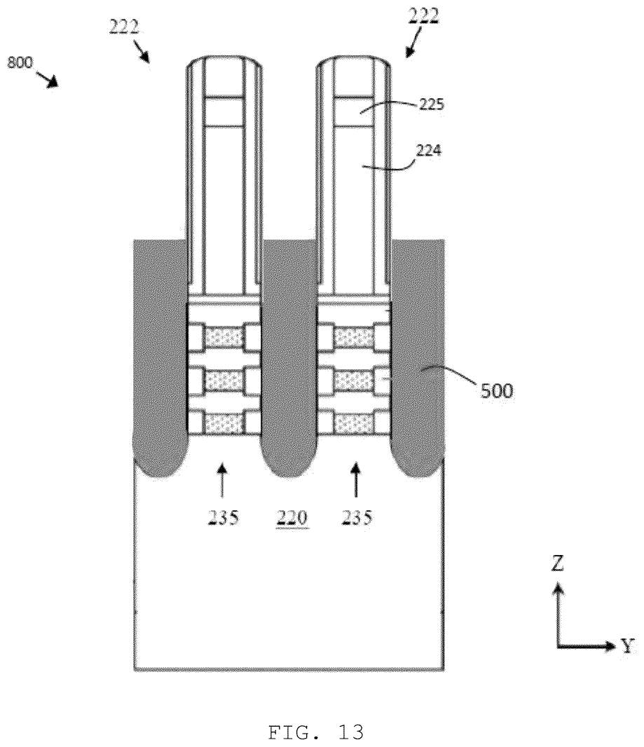

FIG. 13 provides the same cross-sectional view as FIG. 12, at a successive stage of fabrication. As shown in FIG. 13, method 900 (FIG. 1) may continue with operation S926 which forms source/drain features 500 in the cavities 234.

For example, operation S926 may include growing epitaxial material in the cavities 234 to form source/drain features 500. It is noted that the source/drain features 500 may be formed by successive formed layers. In exemplary embodiments, the source/drain features 500 are strained source/drain features 500. Also, the source/drain features 500 may be formed with layers selected for use in an NFET or PFET. In exemplary embodiments, the source/drain features 500 may include N-type epitaxial material source/drain features and P-type epitaxial material source/drain features. The epitaxial material may include one or more layers of Si, SiP, SiC and SiCP for an N-channel FET or Si, SiGe, Ge for a P-channel FET. For the P-channel FET, boron (B) may also be contained in the source/drain. The source/drain epitaxial layers may be formed by an epitaxial growth method using CVD, ALD, or molecular beam epitaxy (MBE).

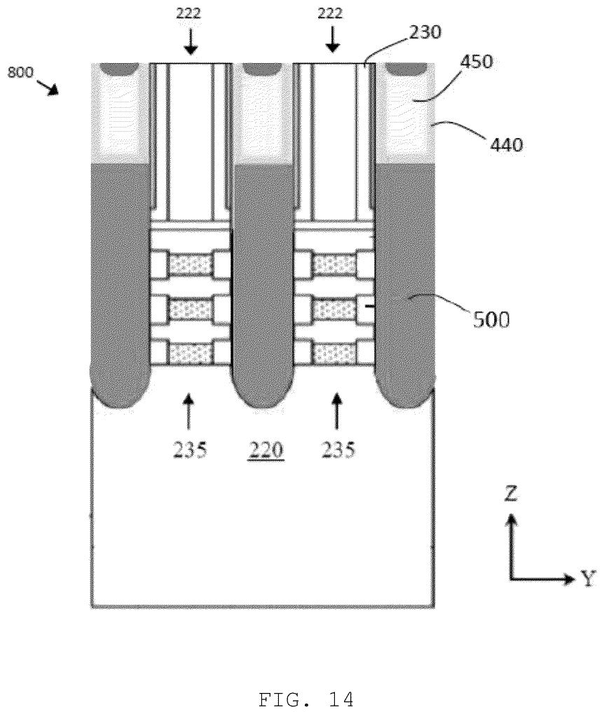

FIG. 14 provides the same cross-sectional view as FIG. 13, at a successive stage of fabrication. As shown in FIG. 14, method 900 (FIG. 1) may continue, at operation S928, with capping the source/drain features 500 with dielectric.

Specifically, a dielectric liner 440 may be formed over source/drain features 500 and along the sides of the sidewall spacers 230. Further, a dielectric 450 may be formed over the liner 440 over the source/drain features 500. Specifically, the cavities 234 are filled with dielectric 450. In exemplary embodiments, the dielectric 450 is a first interlayer dielectric layer (ILD). The dielectric 450 may be silicon oxide or other suitable dielectric material. In certain embodiments, the dielectric liner 440 is a dielectric, such as silicon nitride or another suitable material.

As shown in FIG. 14, the structure 800 may be planarized, such as by a chemical-mechanical planarization (CMP) process. Planarization may remove the mask 225 and uncover the sacrificial gate electrode 224.

Method 900 (FIG. 1) may continue, at operation S930, with performing a process to activate the source/drain features 500. In certain embodiments, operation S930 may be a high temperature anneal process. For example, the high temperature anneal process may be performed at a temperature of at least 1000 degrees C. In other embodiments, the process at may be a low temperature anneal process. For example, the low temperature anneal process may be performed at a temperature of less than 1000 degrees C. During the anneal process, the interposer layer 700 may prevent interdiffusion in the nanosheet layers 216. Specifically, the interposer layer 700 forms a barrier against diffusion of impurities, such as from SiGe or Ge, through vacancy sites in the nanosheet layers 216.

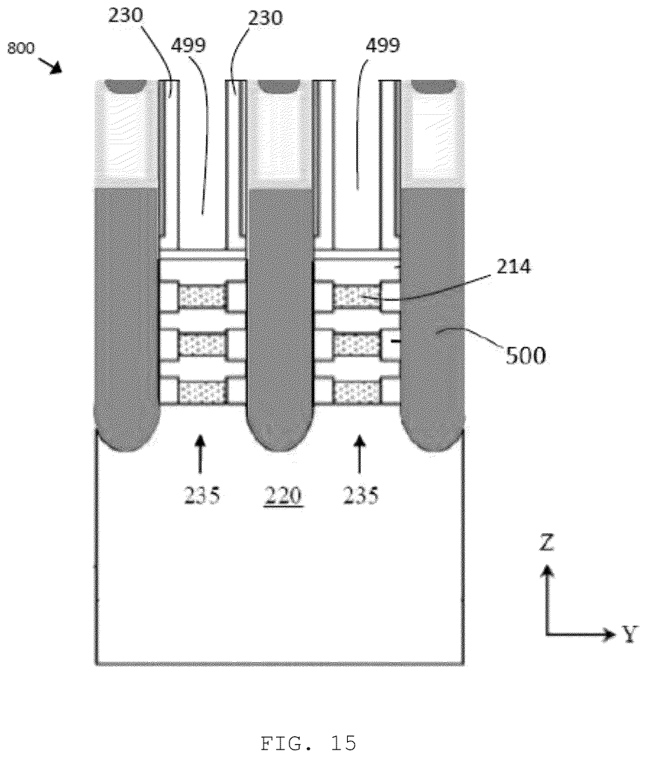

FIG. 15 provides the same cross-sectional view as FIG. 14, at a successive stage of fabrication. As shown in FIG. 15, method 900 (FIG. 1) may continue, at operation S932, with removing the sacrificial gate structures 222. As shown, the sacrificial gate electrode 224 is removed to form gate cavities 499 between sidewall spacers 230.

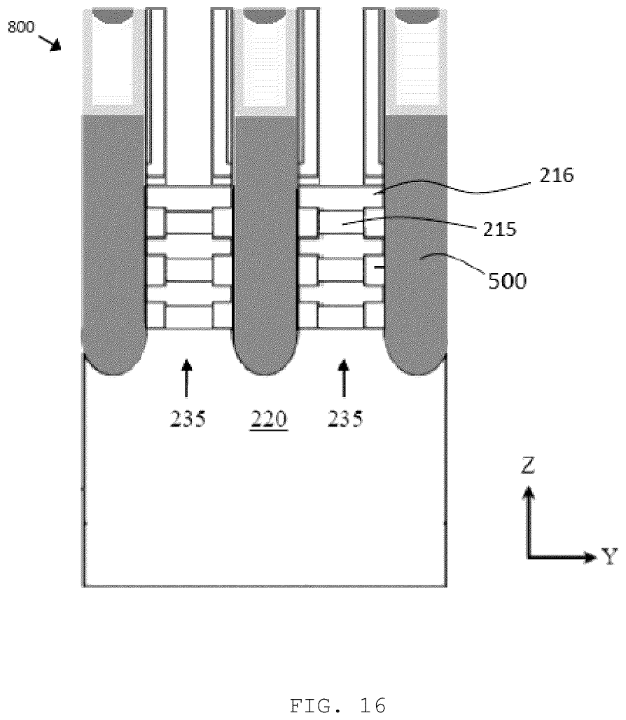

FIG. 16 provides the same cross-sectional view as FIG. 15, at a successive stage of fabrication. As shown in FIG. 16, method 900 (FIG. 1) may continue, at operation S934, with removing the inter-nanosheet portions 730 of the interposer layer 700 from between the nanosheet channel layers 216.

Removing inter-nanosheet portions 730 creates voids 215 around the semiconductor layers 216. In certain embodiments, operation S934 may include a wire-release process to form vertically-spaced nanosheets, in accordance with some embodiments. The wire release process step may also be referred to as a sheet release process step, a sheet formation process step, a nanosheet formation process step or a wire formation process step. In an embodiment the inter-nanosheet portions 730 may be removed using a wet etching process that selectively removes the material of the inter-nanosheet portions 730 without significantly removing the material of the second layers 216 (e.g., silicon (Si)). However, any suitable removal process may be utilized.

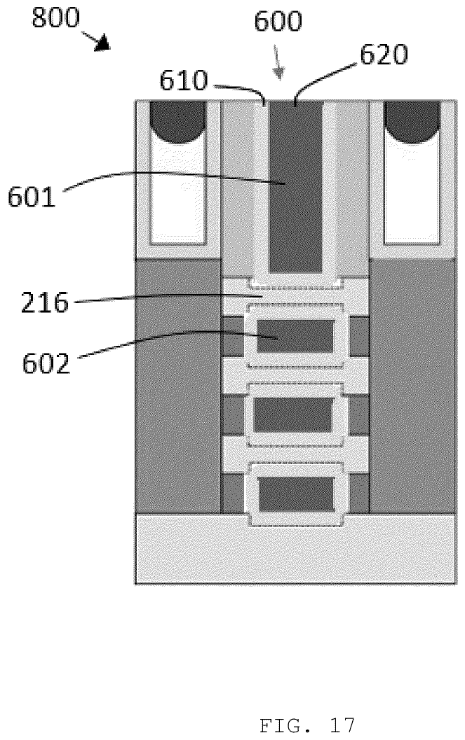

FIG. 17 provides the same cross-sectional view as FIG. 16, at a successive stage of fabrication. As shown in FIG. 17, method 900 (FIG. 1) may continue, at operation S936, with forming metal gates 380 in the gate cavities 499.

Specifically, method 900 may include lining the gate cavities 499 with a dielectric layer or liner 610. For example, a high-K gate dielectric liner 610 may be deposited on the sidewalls of gate cavities 499 and around the nanosheet channel layers 216.

High-K gate dielectrics, as used and described herein, include dielectric materials having a high dielectric constant, for example, greater than that of thermal silicon oxide (about 3.9). An exemplary high-K gate dielectric liner 610 may include a high-K dielectric material such as hafnium oxide (HfO₂). Alternatively, the high-K gate dielectric liner 610 may include other high-K dielectric materials, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. The high-K gate dielectric liner 610 may be formed by ALD, physical vapor deposition (PVD), CVD, oxidation, and/or other suitable methods.

Formation of the metal gates 600 further includes filling the gate cavities 499 with fill material 620. The fill material 620 may include multiple layers of a metal, metal alloy, or metal silicide. The fill material 620 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the fill material 620 may include Ti, Ag, Al, TiAlN, TaC, TaCN, TaSiN, Mn, Zr, TiN, TaN, Ru, Mo, Al, WN, Cu, W, Re, Ir, Co, Ni, other suitable metal materials or a combination thereof. In various embodiments, the fill material 382 may be formed by ALD, PVD, CVD, e-beam evaporation, or other suitable process. Further, the fill material 382 may be formed separately for N-type and P-type transistors which may use different metal layers. In addition, the fill material 620 may provide an N-type or P-type work function, may serve as a transistor gate electrode, and in at least some embodiments, the fill material 620 may include a polysilicon layer. In some examples, the fill material 620 may include selectively-grown tungsten (W) and/or a fluorine-free tungsten (FFW) layer.

As shown in FIG. 17, a chemical mechanical planarization (CMP) process may be performed to remove overburden portions of the liner 610 and fill material 620 to define the metal gates 600 in the gate cavities 499.

As indicated in FIG. 1, method 900 may continue at operation S938 with further processing, such as performing middle end of line (MEOL) processing and back end of line (BEOL) processing.

FIGS. 1 and 2-17 illustrate a method 900 that ensures that all of the interposer layer 700 is removed from the bottom surfaces 233, or at least minimizes an amount of interposer layer 700 remaining on the bottom surfaces 233, before the source/drain features 500 are formed on the bottom surfaces 233. As a result, the epitaxial growth of material forming the source/drain features 500 is improved.

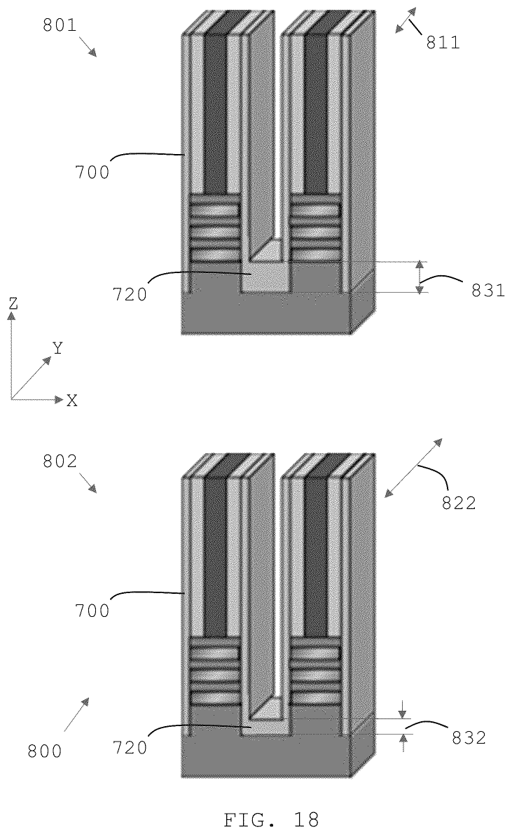

FIG. 18 illustrates a further embodiment of performing method 900.

FIG. 18 illustrates a first region 801 of device 800 and a second region 802 of device 800. Regions 801 and 802 are formed in different areas of substrate 200. Although shown in a vertical alignment in the drawing, the regions 801 and 802 are separated from one another in the X-direction in device 800. In first region 801, the device 800 has a small active area or OD width 811, i.e., from 2 nm to 30 nm, in the Y-direction. In second region 802, the device 800 has a large active area or OD width 822, i.e., from 5 nm to 100 nm, in the Y-direction. In certain embodiments, the large OD width 822 is at least 2 nm greater than the small OD width 821.

FIG. 18 illustrates the device 800 after formation of the interposer layer 700, according to operation S918. Specifically, a deposition process is performed across the device 800, including in device region 801 and in device region 802. Due to the difference in OD widths 811 and 822, the bottom portions 720 are formed with different heights or vertical thicknesses. Specifically, the bottom portion 720 in region 801 has a first thickness 831 and the bottom portion 720 in region 802 has a second thickness 832. As shown, first thickness 831 is greater than second thickness 832. For example, first thickness may be at least 1 nm greater than second thickness 832, such as at least 2 nm, at least 3 nm, at least 5 nm, at least 8 nm, or at least 10 nm greater than second thickness 832.

Thus, in order to remove the bottom portion 720 in first region 801, a greater amount of etching is needed.

During operation S920, a directional etch is used to simultaneously recess the bottom portions 720 in regions 801 and 802. Using a high selectivity etch, such as by controlling the CₓF_{y}/O₂ ratio, overetching of the bottom portion in region 802 may be avoided. Thereafter, method 900 may continue at operation S922 as described above.

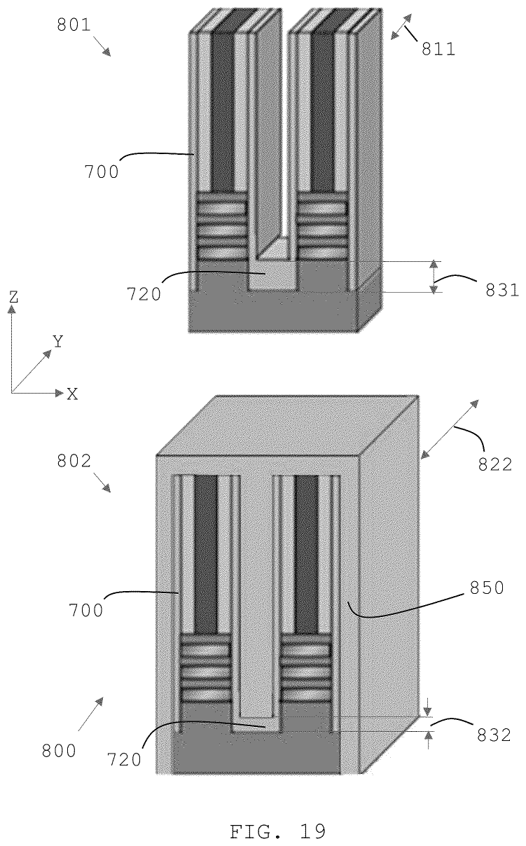

FIG. 19 illustrates a further embodiment of performing method 900.

In FIG. 19 illustrates a first region 801 of device 800 and a second region 802 of device 800. Regions 801 and 802 are formed in different areas of substrate 200. Although shown in a vertical alignment in the drawing, the regions 801 and 802 are separated from one another in the X-direction in device 800. In first region 801, the device 800 has a small active area or OD width 811, i.e., from 2 nm to 30 nm. In second region 802, the device 800 has a large active area or OD width 822, i.e., from 5 nm to 100 nm. In certain embodiments, the large OD width 822 is at least 2 nm greater than the small OD width 821.

FIG. 19 illustrates the device 800 after formation of the interposer layer 700, according to operation S918. Specifically, a deposition process is performed across the device 800, including in device region 801 and in device region 802. Due to the difference in OD widths 811 and 822, the bottom portions 720 are formed with different heights or vertical thicknesses. Specifically, the bottom portion 720 in region 801 has a first thickness 831 and the bottom portion 720 in region 802 has a second thickness 832. As shown, first thickness 831 is greater than second thickness 832.

Thus, in order to remove the bottom portion 720 in first region 801, a greater amount of etching is needed.

In the embodiment of FIG. 19, before performing operation S920, a mask 850 is formed over device region 802 in operation S919 of method 900 as shown. The mask 850 may be formed from photoresist. Thus, operation S920 may be performed with a directional etch that recesses the bottom portion 720 in region 801, but does not etch the bottom portion in region 802. In certain embodiments, the bottom portion 720 in region 801 is recessed and thickness 831 is reduced until the difference between the thicknesses 831 and 832 is no more than 0.5 nm. Specifically, the absolute value operation S920 may be performed until the absolute value of thickness 831 minus thickness 832 is less than or equal to 0.5 nm.

After performing operation S920, the mask may be removed in operation S921. Thereafter, method 900 may continue at operation S922 as described above. By reducing the difference between thicknesses 831 and 832, loading is reduced during the isotropic etch of operation S922 and operation S922 may remove all of the interposer layer 700 from the bottom cavity surface 233 without laterally etching too much of the inter-nanosheet portions 730, i.e., dishing.

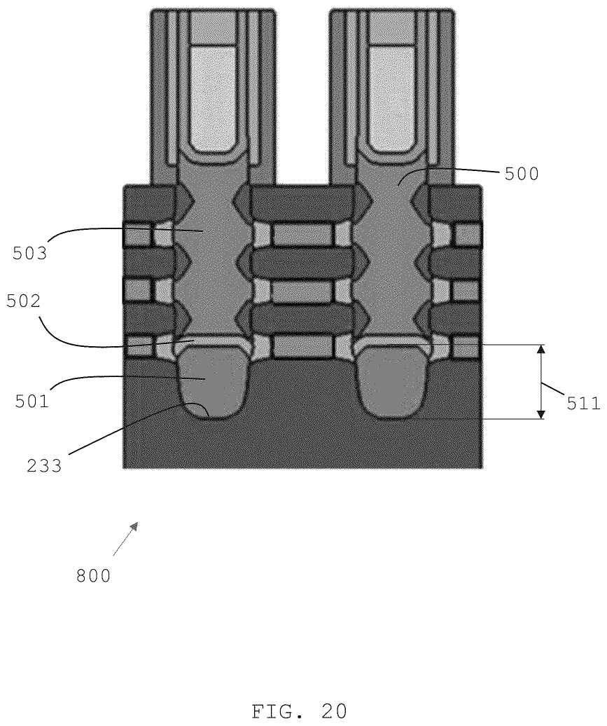

FIG. 20 is a cross-sectional view, similar to FIG. 15, illustrating device 800 after removing the sacrificial gate. As shown, the source/drain features 500 include three different layers, first layer 501, second layer 502, and third layer 503. The first layer 501 is grown directly on the bottom cavity surface 233.

The first, second and third layers 501, 502, and 503 may be formed from different materials. For example, the layers 510, 502, and 503 may be silicon, silicon phosphide (SiP), silicon carbide (SiC), silicon arsenide (SiAs). In some other embodiments, another pentavalent may be used to form the silicon compound, such as antimony (Sb), Bismuth (Bi), moscovium (Mc), other pentavalent silicon compound, or combinations thereof). Each layer 501, 502, and 503 may be formed by an epitaxial growth process. The epitaxial growth process may be a LPCVD process with a silicon-based precursor, a selective epitaxial growth (SEG) process, a cyclic deposition and etching (CDE) process, other suitable processes, or combinations thereof. For example, silicon phosphide crystal may be formed with a chemical gas (Si₃H₈, SiH₃CH₃ and/or PH₃) based deposition process combined with a selective chemical vapor etch process. For another example, silicon crystal may be grown with LPCVD with dichlorosilane (SiH₂Cl₂) as the precursor. The precursor may be doped in-situ (during the epitaxial growth process) or ex-situ (after the epitaxial growth process is completed) with n-type dopants, for example phosphorus (P) for first and second layers 501 and 502, and arsenic (As) for third layer 503, respectively, to form the different epitaxial layers of epitaxial S/D feature 500. In some embodiments, different epitaxial layers of epitaxial S/D feature 500 are doped during deposition by adding impurities to a source material of the epitaxy process. In some embodiments, different layers of epitaxial S/D feature 500 are doped by an ion implantation process subsequent to a deposition process. Implant energies and dosages during the ion implantation process can be configured depends on the design of device 800. For example, first epitaxial layer 501 may be formed by ion implantation doping with a lower concentration of P (for example, a molar ratio of P is less than about 2%) to the silicon precursor for a thickness of about 1 nm to about 10 nm; second epitaxial layer 502 may be formed by ion implantation doping with a higher concentration of P (for example, a molar ratio of P is about 2% to about 10%) to the silicon precursor for a thickness of about 10 nm to about 40 nm; and third epitaxial layer 503 may be formed by ion implantation doping with As (for example, about 1×10²² to about 1×10²³ atoms/cm³ of As, in some embodiments, about 2% to about 10% of As) to the silicon precursor for a thickness of about 0.1 nm to about 20 nm.

As shown in FIG. 20, the first layer 501 has a maximum vertical thickness 511 from a lowest surface to an uppermost surface.

In embodiments herein in which devices 800 are simultaneously formed in device regions 801 having small OD widths and device regions 802 having large OD widths, and in which the devices regions 802 are not masked, i.e., operation S919 is not performed, the maximum vertical thickness 511 of devices 800 in regions 801 is from 1 to 30 nm, and the maximum vertical thickness 511 of devices 800 in regions 802 is from 1 to 30 nm. Further, in such embodiments, the maximum vertical thicknesses 511 in regions 802 are at least 0.2 nm greater than the maximum vertical thicknesses 511 in regions 801 due to the high amount of oxide etched in regions 802.

These dimensions result from the etching process removing more oxide in the device regions 802 as compared to device regions 801.

In embodiments herein in which devices 800 are simultaneously formed in device regions 801 having small OD widths and device regions 802 having large OD widths, and in which the devices regions 802 are masked, i.e., operation S919 is performed, the maximum vertical thickness 511 of devices 800 in regions 801 is from 1 to 30 nm, and the maximum vertical thickness 511 of devices 800 in regions 802 is from 1 to 30 nm. Further, in such embodiments, the difference in maximum vertical thicknesses 511 between regions 801 and 802 are no more than 0.5 nm due to the selective area control provided by selectively etching the thicker bottom portions 720 in regions 801 while regions 802 are masked.

In an embodiment, a method includes in a first device region and in a second device region: forming a stack of first epitaxial layers and second epitaxial layers; forming a sacrificial gate over the stack; etching the stack to form a cavity having a bottom surface; removing the first epitaxial layers to form gaps; and depositing an interposer material over the bottom surface and in the gaps; in the first device region: performing an anisotropic etch of the interposer material located over the bottom surface; and in the first device region and in the second device region: performing an isotropic etch of the interposer material to remove the interposer material located over the bottom surface and to laterally recess the interposer material in the gaps.

In certain embodiments of the method, performing the isotropic etch forms lateral recesses, and the method further includes: forming inner spacers in the lateral recesses; forming a source/drain feature in the cavity; removing the sacrificial gate to form a gate cavity; and forming a metal gate in the gate cavity.

In certain embodiments, the method further includes masking the second device region with a mask before performing the anisotropic etch; and removing the mask from the second device region before performing the isotropic etch.

In certain embodiments, the method further includes forming a source/drain feature in the cavity, including a first layer of epitaxial material formed on the bottom surface, wherein in the first device region, the first layer of epitaxial material has a first thickness of from 1 to 30 nm; in the second device region, the first layer of epitaxial material has a second thickness of from 1 to 30 nm; and a difference between the first thickness and the second thickness is at least 0.2 nm.

In certain embodiments of the method, the anisotropic etch of the interposer material located over the bottom surface is performed in the second device region.

In certain embodiments of the method, after depositing the interposer material, the interposer material over the bottom surface in the first device region has a first initial thickness, and the interposer material over the bottom surface in the second device region has a second initial thickness; a difference between the first initial thickness and the second initial thickness is at least 1 nm; after performing the anisotropic etch of the interposer material located over the bottom surface, the interposer material over the bottom surface in the first device region has a first recessed thickness, and the interposer material over the bottom surface in the second device region remains having the second initial thickness; and a difference between the first recessed thickness and the second initial thickness is no more than 0.5 nm.

In certain embodiments, the method further includes forming a source/drain feature in the cavity, including a first layer of epitaxial material formed on the bottom surface, wherein in the first device region, the first layer of epitaxial material has a first thickness of from 1 to 30 nm; in the second device region, the first layer of epitaxial material has a second thickness of from 1 to 30 nm; and a difference between the first thickness and the second thickness is less than 0.5 nm.

In certain embodiments of the method, depositing the interposer material over the bottom surface and in the gaps includes filling the gaps with the interposer material.

In certain embodiments of the method, the interposer material is silicon oxide.

In certain embodiments of the method, a remnant of the interposer material remains on the bottom surface after performing the isotropic etch, and wherein the remnant has a vertical thickness of less than 0.2 nm.

In another embodiment, a method includes forming a stack of first epitaxial layers and second epitaxial layers; etching the stack to form a cavity having a bottom surface; removing the first epitaxial layers to form gaps; depositing an interposer material over the bottom surface and in the gaps; recessing the interposer material located over the bottom surface, wherein a remaining portion of the interposer material remains over the bottom surface; and performing an isotropic etch of the interposer material to remove the remaining portion of the interposer material located over the bottom surface and to laterally recess the interposer material in the gaps.

In certain embodiments of the method, performing the isotropic etch forms lateral recesses, and wherein the method further includes: forming inner spacers in the lateral recesses; forming a source/drain feature in the cavity; and forming a metal gate adjacent to the source/drain feature.

In certain embodiments of the method, depositing the interposer material over the bottom surface and in the gaps includes filling the gaps with the interposer material.

In certain embodiments of the method, the interposer material is silicon oxide.

In certain embodiments of the method, a remnant of the interposer material remains on the bottom surface after performing the isotropic etch, and wherein the remnant has a vertical thickness of less than 0.2 nm.

In another embodiment, a method includes forming a stack of first epitaxial layers and second epitaxial layers; forming sacrificial gates over the stack; etching the stack to form cavities having bottom surfaces; removing the first epitaxial layers to form gaps; depositing an interposer material over the bottom surface and in the gaps; directionally etching the interposer material located over selected bottom surfaces; and isotropically etching the interposer material to remove the interposer material located over the bottom surfaces and to laterally recess the interposer material in the gaps.

In certain embodiments, the method further includes masking non-selected bottom surfaces before directionally etching the interposer material located over the selected bottom surfaces; and de-masking the non-selected bottom surfaces before isotropically etching the interposer material.

In certain embodiments of the method, the method includes directionally etching the interposer material located over non-selected bottom surfaces while directionally etching the interposer material located over the selected bottom surfaces.

In certain embodiments, the method further includes forming a source/drain feature in the cavity, including a first layer of epitaxial material formed on the bottom surface, wherein: over selected bottom surfaces, the first layer of epitaxial material has a first thickness of from 1 to 30 nm; over non-selected bottom surfaces, the first layer of epitaxial material has a second thickness of from 1 to 30 nm; and a difference between the first thickness and the second thickness is at least 0.2 nm.

In certain embodiments, the method further includes forming a source/drain feature in the cavity, including a first layer of epitaxial material formed on the bottom surface, wherein: over selected bottom surfaces, the first layer of epitaxial material has a first thickness of from 1 to 30 nm; over non-selected bottom surfaces, the first layer of epitaxial material has a second thickness of from 1 to 30 nm; and a difference between the first thickness and the second thickness is no more than 0.5 nm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
in a first device region and in a second device region:
forming a stack of first epitaxial layers and second epitaxial layers;
forming a sacrificial gate over the stack;
etching the stack to form a cavity having a bottom surface;
removing the first epitaxial layers to form gaps; and
depositing an interposer material over the bottom surface and in the gaps;
in the first device region:
performing an anisotropic etch of the interposer material located over the bottom surface; and
in the first device region and in the second device region:
performing an isotropic etch of the interposer material to remove the interposer material located over the bottom surface and to laterally recess the interposer material in the gaps.

2. The method of claim 1, wherein performing the isotropic etch forms lateral recesses, and wherein the method further comprises:
forming inner spacers in the lateral recesses;
forming a source/drain feature in the cavity;
removing the sacrificial gate to form a gate cavity; and
forming a metal gate in the gate cavity.

3. The method of claim 1, further comprising:
masking the second device region with a mask before performing the anisotropic etch; and
removing the mask from the second device region before performing the isotropic etch.

4. The method of claim 3, further comprising forming a source/drain feature in the cavity, including a first layer of epitaxial material formed on the bottom surface, wherein
in the first device region, the first layer of epitaxial material has a first thickness of from 1 to 30 nm;
in the second device region, the first layer of epitaxial material has a second thickness of from 1 to 30 nm; and
a difference between the first thickness and the second thickness is at least 0.2 nm.

5. The method of claim 1, wherein the anisotropic etch of the interposer material located over the bottom surface is performed in the second device region.

6. The method of claim 5, wherein:
after depositing the interposer material, the interposer material over the bottom surface in the first device region has a first initial thickness, and the interposer material over the bottom surface in the second device region has a second initial thickness;
a difference between the first initial thickness and the second initial thickness is at least 1 nm;
after performing the anisotropic etch of the interposer material located over the bottom surface, the interposer material over the bottom surface in the first device region has a first recessed thickness, and the interposer material over the bottom surface in the second device region remains having the second initial thickness; and
a difference between the first recessed thickness and the second initial thickness is no more than 0.5 nm.

7. The method of claim 5, further comprising forming a source/drain feature in the cavity, including a first layer of epitaxial material formed on the bottom surface, wherein
in the first device region, the first layer of epitaxial material has a first thickness of from 1 to 30 nm;
in the second device region, the first layer of epitaxial material has a second thickness of from 1 to 30 nm; and
a difference between the first thickness and the second thickness is less than 0.5 nm.

8. The method of claim 1, wherein depositing the interposer material over the bottom surface and in the gaps comprises filling the gaps with the interposer material.

9. The method of claim 1, wherein the interposer material is silicon oxide.

10. The method of claim 1, wherein a remnant of the interposer material remains on the bottom surface after performing the isotropic etch, and wherein the remnant has a vertical thickness of less than 0.2 nm.

11. A method comprising:
forming a stack of first epitaxial layers and second epitaxial layers;
etching the stack to form a cavity having a bottom surface;
removing the first epitaxial layers to form gaps;
depositing an interposer material over the bottom surface and in the gaps;
recessing the interposer material located over the bottom surface, wherein a remaining portion of the interposer material remains over the bottom surface; and
performing an isotropic etch of the interposer material to remove the remaining portion of the interposer material located over the bottom surface and to laterally recess the interposer material in the gaps.

12. The method of claim 11, wherein performing the isotropic etch forms lateral recesses, and wherein the method further comprises:
forming inner spacers in the lateral recesses;
forming a source/drain feature in the cavity; and
forming a metal gate adjacent to the source/drain feature.

13. The method of claim 11, wherein depositing the interposer material over the bottom surface and in the gaps comprises filling the gaps with the interposer material.

14. The method of claim 11, wherein the interposer material is silicon oxide.

15. The method of claim 11, wherein a remnant of the interposer material remains on the bottom surface after performing the isotropic etch, and wherein the remnant has a vertical thickness of less than 0.2 nm.

16. A method comprising:
forming a stack of first epitaxial layers and second epitaxial layers;
forming sacrificial gates over the stack;
etching the stack to form cavities having bottom surfaces;
removing the first epitaxial layers to form gaps;
depositing an interposer material over the bottom surfaces and in the gaps;
directionally etching the interposer material located over selected bottom surfaces; and
isotropically etching the interposer material to remove the interposer material located over the bottom surfaces and to laterally recess the interposer material in the gaps.

17. The method of claim 16, further comprising:
masking non-selected bottom surfaces before directionally etching the interposer material located over the selected bottom surfaces; and
de-masking the non-selected bottom surfaces before isotropically etching the interposer material.

18. The method of claim 16, wherein the method comprises directionally etching the interposer material located over non-selected bottom surfaces while directionally etching the interposer material located over the selected bottom surfaces.

19. The method of claim 16, further comprising forming a source/drain feature, including a first layer of epitaxial material formed on the bottom surface, wherein:
over selected bottom surfaces, the first layer of epitaxial material has a first thickness of from 1 to 30 nm;
over non-selected bottom surfaces, the first layer of epitaxial material has a second thickness of from 1 to 30 nm; and
a difference between the first thickness and the second thickness is at least 0.2 nm.

20. The method of claim 16, further comprising forming a source/drain feature, including a first layer of epitaxial material formed on the bottom surface, wherein:
over selected bottom surfaces, the first layer of epitaxial material has a first thickness of from 1 to 30 nm;
over non-selected bottom surfaces, the first layer of epitaxial material has a second thickness of from 1 to 30 nm; and
a difference between the first thickness and the second thickness is no more than 0.5 nm.
